(19) United States
(12) Patent Application Publication
(10) Pub. No.: US 2026/0040968 A1
(43) Pub. Date: Feb. 5, 2026

(54) PACKAGE STRUCTURE AND PACKAGE METHOD

(71) Applicant: JCET Group Co., LTD., Jiangyin (CN)

(72) Inventors: Sunyan WANG, Jiangyin (CN); Huihui WANG, Jiangyin (CN); Yaqin WANG, Jiangyin (CN); Kai LIU, Jiangyin (CN); Yangyang HAN, Jiangyin (CN)

(73) Assignee: JCET Group Co., LTD., Jiangyin (CN)

(21) Appl. No.: 19/289,256

(22) Filed: Aug. 4, 2025

(30) Foreign Application Priority Data
Aug. 5, 2024 (CN) 202411075937.5

(51) Int. Cl. H01L 23/538; H01L 23/00; H01L 23/31; H01L 23/498; H01L 25/18

(52) U.S. Cl. CPC H01L 23/5385; H01L 23/5386; H01L 24/16; H01L 24/29; H01L 24/32; H01L 24/73; H01L 25/18; H01L 23/3107; H01L 23/49816; H01L 2224/16227; H01L 2224/2919; H01L 2224/32225; H01L 2224/73204

(57) ABSTRACT

A package structure includes a substrate having conductive lines along a direction parallel to a surface of the substrate, and an optoelectronic chip bonded on the first substrate. A part of areas of the substrate is a first substrate, and remaining areas of the substrate are a second substrate. A base material of the first substrate is a light-transparent material, the first substrate has the conductive lines, and a base material of the second substrate is a non-light-transparent material. An active area of the optoelectronic chip is oriented toward the first substrate. The active area is arranged staggered with the conductive lines in the first substrate, and the optoelectronic chip is electrically connected with the conductive lines in the first substrate.

### CROSS-REFERENCE TO RELATED APPLICATIONS

This application claims the benefit of priority to Chinese Application No. 202411075937.5, filed on Aug. 5, 2024, which is hereby incorporated by reference in its entirety.

### TECHNICAL FIELD

Embodiments of the present disclosure relate to the technical field of semiconductor package, and particularly relate to a package structure and a package method.

### BACKGROUND

With the development of technology, people also set higher requirements for the functionality of electronic devices, thus making the types of electronic elements integrated into the package structure more diversified. For example, currently, electronic devices are usually configured with package structures containing optoelectronic chips.

The current package methods mainly mount optoelectronic chips on a substrate, and after molding, the area above the optoelectronic chips is not blocked by non-light-transparent materials, thereby achieving the transmission or reception of light to or from the optoelectronic chips.

However, the performance of the current package structure still needs to be improved.

### SUMMARY

Embodiments of the present disclosure provide a package structure comprising: a substrate having conductive lines, along a direction parallel to a surface of the substrate, a part of areas of the substrate being a first substrate, and the remaining areas of the substrate being a second substrate, and the base material of the first substrate is a light-transparent material and the first substrate has in it conductive lines, the base material of the second substrate is a non-light-transparent material; and an optoelectronic chip, bonded on the first substrate, the active area of the optoelectronic chip is oriented toward the first substrate, and the active area is arranged staggered with conductive lines in the first substrate, the optoelectronic chip being electrically connected with the conductive lines in the first substrate.

Optionally, the package structure further comprises: a first conductive bump, located between the optoelectronic chip and the first substrate and realizing an electrical connection between the optoelectronic chip and the conductive lines in the first substrate.

Optionally, the package structure further comprises: a molding layer, located on the first substrate and covering the optoelectronic chip, the molding layer exposing a surface of the first substrate facing away from the optoelectronic chip; and a first filler layer, located between the optoelectronic chip and the first substrate and covering the first conductive bump, the first filler layer being a light-transparent material.

Optionally, the material of the first filler layer comprises a light-transparent resin.

Optionally, the optoelectronic chip serves as a first electronic element, and the package structure further comprises: a second electronic element, located on the substrate in the remaining area and electrically connected with conductive lines in the substrate in the remaining area, and the functional type of the second electronic element is different from that of the first electronic element.

Optionally, the first substrate and the second substrate are arranged side-by-side in a direction parallel to the surface of the substrate; or the second substrate has in it an opening passing through the second substrate, and the opening comprises a first opening and a second opening that are connected through each other, the opening dimension of the first opening is larger than the opening dimension of the second opening; the first substrate is located in the first opening; the active area of the optoelectronic chip is arranged opposite to the second opening.

Optionally, in the case that the second substrate has in it an opening passing through the second substrate, at least a part of the conductive lines in the first substrate are electrically connected with the conductive lines in the second substrate exposed at the first opening.

Optionally, at least a part of the conductive lines in the first substrate are electrically connected with conductive lines in the second substrate exposed at the bottom of the first opening.

Optionally, the substrate is a one-piece formed substrate, and the sidewalls of the first substrate and the second substrate are in contact; or the first substrate and the second substrate are independent of each other.

Optionally, the first substrate and second substrate are independent of each other and spaced apart from each other, and the sidewalls of the first substrate and second substrate enclose a groove; the package structure further comprises: a second filler layer of non-light-transparent material, filled in the grooves.

Optionally, the material of the second filler layer comprises a resin or bonding adhesive.

Optionally, the package structure further comprises: a molding layer, located on the first substrate and covering the optoelectronic chip, the molding layer exposing a surface of the first substrate facing away from the optoelectronic chip, and the molding layer also is filled in the grooves, the molding layer in the groove serving as a second filler layer; or the package structure further comprises: a pre-molding layer, filled in the grooves, the pre-molding layer in the grooves serving as a second filler layer.

Optionally, the second substrate surrounds the sidewall of the first substrate.

Optionally, the first substrate and the second substrate have conductive lines that are conducting with each other.

Optionally, the first and second substrates are independent of each other; the package structure comprises: a first electrode, located on a first surface of the substrate and electrically connected with the conductive lines, the first surface being used to support the optoelectronic chip; a second electrode, located on a second surface of the substrate and electrically connected with the conductive lines, the second surface being used to surface away from the optoelectronic chip; the first substrate and the second substrate satisfy one or two of the following conditions: the first substrate and the second substrate have connected first electrodes; the first substrate and the second substrate have connected second electrodes.

Optionally, the package structure comprises: a first electrode, located on a first surface of the first substrate and electrically connected with the conductive line, the first surface being used to support an optoelectronic chip; a second electrode, located on a second surface of the first substrate and electrically connected with the conductive line, the second surface being used to surface away from the optoelectronic chip; a first passivation layer, located on the first surface of the first substrate and exposing the first electrode, the first passivation layer has in it a third opening passing through the first passivation layer, the third opening being arranged opposite to the active area of the optoelectronic chip; a second passivation layer, located on the second surface of the first substrate and exposing the second electrode, the second passivation layer has in it a fourth opening passing through the second passivation layer, the fourth opening being arranged opposite to the third opening; and the active area of the optoelectronic chip is arranged opposite to the third opening and the fourth opening.

Optionally, the material of the base material of the first substrate comprises one or more of glass, silica gel, acrylic, silicon nitride and silicon oxide.

Optionally, the package structure further comprises: a molding layer, located on the first substrate and covering the optoelectronic chip, the molding layer exposing a surface of the first substrate facing away from the optoelectronic chip, and the molding layer further covering the sidewall of the first substrate.

Optionally, the package structure further comprises: a second conductive bump, located on a second surface of the first substrate, the second conductive bump being electrically connected with the conductive lines, the second surface being facing away from the optoelectronic chip.

Optionally, the optoelectronic chip comprises one or more of a light-sensitive chip and a light-emitting chip.

Correspondingly, embodiments of the present disclosure also provide a package method comprising: providing a substrate having conductive lines, along a direction parallel to a surface of the substrate, a part of areas of the substrate being a first substrate, and the remaining areas of the substrate being a second substrate, the base material of the first substrate is a light-transparent material and the first substrate has in it conductive lines, the base material of the second substrate is a non-light-transparent material; and bonding an optoelectronic chip on the first substrate, the active area of the optoelectronic chip is oriented toward the first substrate and the active area is arranged staggered with conductive lines in the first substrate, the optoelectronic chip being electrically connected with the conductive lines in the first substrate.

Optionally, the optoelectronic chip serves as a first electronic element, and the package method further comprises: disposing a second electronic element on the substrate in the remaining areas, the second electronic element being electrically connected with conductive lines in the substrate in the remaining areas, and the functional type of the second electronic element being different from the functional type of the first electronic element.

Optionally, the step of providing a substrate having conductive lines comprises: providing a one-piece formed substrate, the sidewalls of the first substrate and the second substrate are in contact.

Optionally, the step of providing a one-piece formed substrate comprises: providing a carrier substrate comprising a first area and a second area adjacent to each other; performing one or more wiring treatments on the carrier substrate and forming a first substrate located in the first area and a second substrate located in the second area, and obtaining a one-piece formed substrate; the step of wiring treatments comprises: forming a base material on the carrier substrate, comprising a first base material formed in the first area and a second base material formed in the second area, the first base material being a light-transparent material; and forming conductive lines on the surface or in the interior of the base material in the first area and in the second area; wherein in the case that the number of the wiring treatments is a plurality of times, the first base material formed by the plurality of the wiring treatments constitutes a stacked structure, and the second base material formed by the plurality of the wiring treatments constitutes a stacked structure; after obtaining the one-piece formed substrate, the package method further comprises: removing the carrier substrate.

Optionally, the step of providing a substrate having conductive lines comprises: providing a carrier substrate; arranging a first substrate and a second substrate on the carrier substrate, respectively, so that the first substrate and the second substrate form a substrate; the package method further comprises: forming, on the first substrate, a molding layer covering the optoelectronic chip, the molding layer exposing a surface of the first substrate facing away from the optoelectronic chip; after forming a molding layer covering the optoelectronic chip, the package method further comprises: removing the carrier substrate.

Optionally, the step of providing a substrate having conductive lines comprises: providing a second substrate, the second substrate has in it an opening passing through the second substrate, the opening comprises a first opening and a second opening that are connected through each other, the opening dimension of the first opening is larger than the opening dimension of the second opening; a first substrate is arranged in the first opening such that the first substrate and the second substrate form a substrate; in the step of bonding an optoelectronic chip on the first substrate, the active area of the optoelectronic chip is arranged opposite to the second opening.

Optionally, in the step of providing a first substrate in the first opening, at least a part of the conductive lines in the first substrate are electrically connected with the conductive lines in the second substrate exposed at the first opening.

Optionally, in the step of providing a first substrate in the first opening, at least a part of the conductive lines in the first substrate are electrically connected with the conductive lines in the second substrate exposed at the bottom of the first opening.

Optionally, after making the first substrate and second substrate form a substrate, the optoelectronic chip is bonded on the first substrate; or, after bonding the optoelectronic chip on the first substrate, the first substrate and second substrate are made to form a substrate.

Optionally, the step of bonding an optoelectronic chip on the first substrate comprises: bonding the optoelectronic chip to the first substrate using a first conductive bump to realize an electrical connection between the optoelectronic chip and conductive lines in the first substrate.

Optionally, the package method further comprises: forming, on the first substrate, a molding layer covering the optoelectronic chip, the molding layer exposing a surface of the first substrate facing away from the optoelectronic chip; after bonding an optoelectronic chip on the first substrate and before forming a molding layer covering the optoelectronic chip, the package method further comprises: forming a first filler layer between the optoelectronic chip and the first substrate, the first filler layer covering the first conductive bump, the first filler layer being a light-transparent material.

Optionally, the first substrate and second substrate are independent of each other and spaced apart from each other, and the sidewalls of the first substrate and second substrate enclose a groove; the package method further comprises: filling the groove with a second filler layer of a non-light-transparent material.

Optionally, the package method further comprises: forming, on the first substrate, a molding layer covering the optoelectronic chip, the molding layer exposing a surface of the first substrate facing away from the optoelectronic chip; and in the step of forming the molding layer covering the optoelectronic chip, the molding layer is also filled in the groove and serves as a second filler layer; or the step of filling the groove with a second filler layer of a non-light-transparent material comprises: pre-molding the first substrate and the second substrate to form a pre-molding layer filled in the groove, the pre-molding layer serving as a second filler layer.

Optionally, the second substrate surrounds the sidewall of the first substrate.

Optionally, the package method further comprises forming, on the first substrate, a molding layer covering the optoelectronic chip, the molding layer exposing a surface of the first substrate facing away from the optoelectronic chip; and the molding layer further covering the sidewall of the first substrate.

Optionally, in the step of providing a substrate with conductive lines, the first substrate and second substrate are independent of each other; and the package method further comprises: forming, on the substrate, one or two of a first electrode and a second electrode; wherein the first electrode is located on a first surface of the substrate, the first substrate and the second substrate have connected first electrodes, and the first electrodes are electrically connected with the conductive lines, and the first surface is used to support the optoelectronic chip; the second electrode is located on a second surface of the substrate, the first substrate and the second substrate have connected second electrodes, and the second electrodes are electrically connected with the conductive lines, and the second surface is used to face away from the optoelectronic chip.

Optionally, a first electrode electrically connected with the conductive lines and a first passivation layer covering the first surface and exposing the first electrode are formed on the first surface of the first substrate, the first passivation layer has in it a third opening passing through the first passivation layer, a second electrode electrically connected with the conductive lines and a second passivation layer covering the second surface and exposing the second electrode are formed on the second surface of the first substrate, the second passivation layer has in it a fourth opening passing through the second passivation layer, the fourth opening being arranged opposite to the third opening, the first surface being used to support an optoelectronic chip, the second surface being facing away from the first surface; in the step of bonding an optoelectronic chip on the first substrate, the active area of the optoelectronic chip is arranged opposite to the third opening and the fourth opening.

Optionally, the package method further comprises forming, on a second surface of the first substrate, a second conductive bump electrically connected with the conductive lines, the second surface being facing away from the optoelectronic chip.

### BRIEF DESCRIPTION OF THE DRAWINGS

FIG. 1 is a structural schematic diagram of a package structure;

FIG. 2 is a structural schematic diagram of a package structure of a first embodiment of the present disclosure;

FIG. 3 is a structural schematic diagram of a package structure of a second embodiment of the present disclosure;

FIG. 4 is a structural schematic diagram of a package structure of a third embodiment of the present disclosure;

FIG. 5 is a structural schematic diagram of a package structure of a fourth embodiment of the present disclosure;

FIG. 6 is a structural schematic diagram of a package structure of a fifth embodiment of the present disclosure;

FIG. 7 is a structural schematic diagram of a package structure of a sixth embodiment of the present disclosure;

FIG. 8 is a structural schematic diagram of a package structure of a seventh embodiment of the present disclosure;

FIG. 9 is a schematic diagram corresponding to the step of providing a substrate in a first embodiment of the package method of the present disclosure;

FIG. 10 is a schematic diagram of a process of mounting an electronic element onto a substrate in the first embodiment of the package method of the present disclosure;

FIG. 11 is a schematic diagram of the first embodiment of the package method of the present disclosure after forming a first filler layer between an optoelectronic chip and a first substrate;

FIG. 12 is a schematic diagram corresponding to the step of forming a molding layer covering an optoelectronic chip on the first substrate in the first embodiment of the package method of the present disclosure;

FIG. 13 is a schematic diagram corresponding to the step of removing a carrier substrate and forming a second conductive bump on a second surface of the first substrate in the first embodiment of the package method of the present disclosure;

FIG. 14 is a schematic diagram corresponding to the steps of providing a carrier substrate and providing a first substrate and a second substrate on the carrier substrate, respectively, in a second embodiment of the package method of the present disclosure;

FIG. 15 is a schematic diagram corresponding to the step of filling the groove with the second filler layer of a non-light-transparent material in the second embodiment of the package method of the present disclosure;

FIG. 16 is a schematic diagram corresponding to the step of forming a first electrode on a first surface of a substrate in the second embodiment of the package method of the present disclosure;

FIG. 17 is a schematic diagram corresponding to the step of removing a carrier substrate and forming a second electrode on a second surface of the substrate in the second embodiment of the package method of the present disclosure;

FIG. 18 is a schematic diagram corresponding to the step of providing a second substrate in a third embodiment of the package method of the present disclosure;

FIG. 19 is a schematic diagram corresponding to the step of providing a first substrate in a first opening in the third embodiment of the package method of the present disclosure;

FIG. 20 is a schematic diagram corresponding to the steps of bonding an electronic element on a substrate and forming a molding layer in the third embodiment of the package method of the present disclosure;

FIG. 21 is a schematic diagram corresponding to the step of providing a one-piece formed substrate in a fourth embodiment of the package method of the present disclosure; and

FIG. 22 is a schematic diagram corresponding to the steps of forming a first electrode and a first passivation layer on the first surface of the first substrate, and forming a second electrode and a second passivation layer on the second surface of the first substrate, in the fourth embodiment of the package method of the present disclosure.

### DETAILED DESCRIPTIONS

As can be seen from the background technology, currently, the performance of the package structure still needs to be improved. In connection with a package structure, the reason why its performance is yet to be improved is now analyzed. It is a problem to be solved by the embodiments of the present disclosure to provide a package method and a package structure, which improve the performance of the package structure and reduce the occupied space of the packaging structure.

The technical solution of the embodiments of the present disclosure has the following advantages.

In the package structure provided by the embodiments of the present disclosure, an optoelectronic chip is bonded on a light-transparent first substrate and electrically connected with the conductive lines in the first substrate, and the active area of the optoelectronic chip is oriented toward the first substrate, and since the base material of the first substrate is a light-transparent material, the active area of the optoelectronic chip is able to receive or emit light through the first substrate to meet the normal work requirements of the optoelectronic chip; moreover, the first substrate is not only capable of realizing electrical connection with the optoelectronic chip, but also capable of realizing sealing protection for the optoelectronic chip, and the use of the first substrate with composite function makes the structure of the package structure simpler and reduces the thickness and volume of the package structure; furthermore, the optoelectronic chip is bonded on the first substrate, and the optoelectronic chip is firmly bonded to the first substrate; in summary, the performance of the package structure can be improved while the space occupied is reduced.

In the package method provided by the embodiments of the present disclosure, an optoelectronic chip is bonded on a light-transparent first substrate, an active area of the optoelectronic chip is oriented toward the first substrate, and the optoelectronic chip is electrically connected with the conductive lines in the first substrate; since the base material of the first substrate is a light-transparent material, the active area of the optoelectronic chip is able to receive or emit light through the first substrate to meet the normal work requirements of the optoelectronic chip; moreover, the first substrate is not only capable of realizing electrical connection with the optoelectronic chip, but also capable of realizing sealing protection for the optoelectronic chip, and the use of the first substrate with composite function makes the structure of the package structure simpler and reduces the thickness and volume of the package structure; furthermore, the optoelectronic chip is bonded on the first substrate, and the optoelectronic chip is firmly bonded to the first substrate; in summary, the performance of the package structure can be improved while the space occupied is reduced.

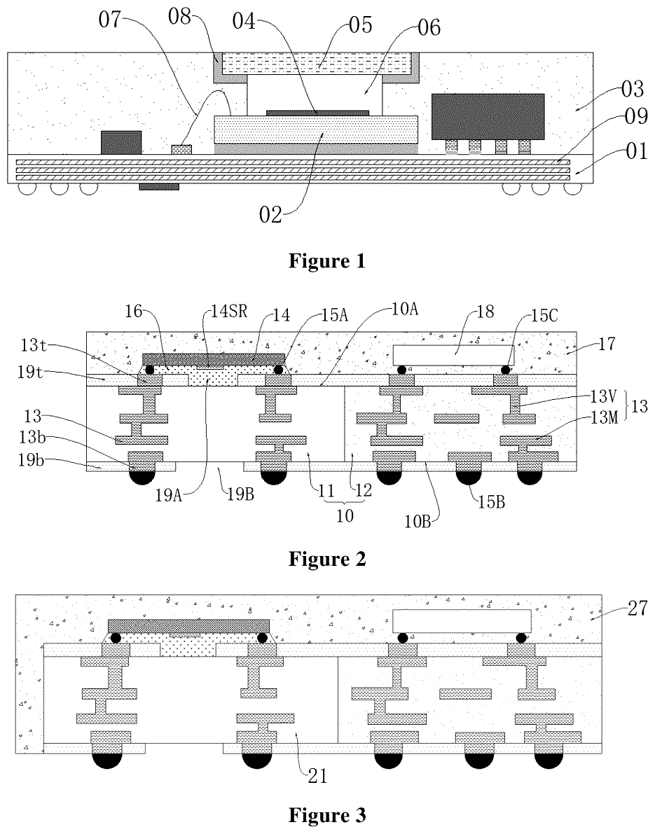

FIG. 1 is a structural schematic diagram of a package structure.

Referring to FIG. 1, the package structure includes: a substrate 01 having a conductive line 09; an optoelectronic chip 02, mounted on the substrate 01, and an active area 04 of the optoelectronic chip 02 facing away from the substrate 01; a lead wire 07, one end of the lead wire is electrically connected with the optoelectronic chip 02, and the other end of the lead wire is electrically connected with the conductive line 09 in the substrate 01; a molding layer 03, located on the substrate 01 and covering the optoelectronic chip 02, the molding layer 03 has in it a hollow cavity 06 in the molding layer 03 located at the top of the active area 04; a light-transparent cover plate 05, assembled in the hollow cavity 06 by means of an adhesive layer 08, the light-transparent cover plate 05 being arranged opposite to the active area 04 of the optoelectronic chip 02 and spaced apart from the optoelectronic chip 02.

The current package structure mainly adopts a mounting method to install the optoelectronic chip 02 on the substrate 01, adopts a lead wire bonding method to realize an electrical connection with the substrate 01, and installs a light-transparent cover plate 05 above the optoelectronic chip 02, the active area 04 receives or sends light through the light-transparent cover plate 05 when the optoelectronic chip 02 is operating, and at the same time, the light-transparent cover plate 05 also realizes a sealing protection of the optoelectronic chip 02.

It has been found that since the light-transparent cover plate 05 is assembled in the hollow cavity 06 by means of the adhesive layer 08, the adhesive layer 08 at the junction of the light-transparent cover plate 05 and the hollow cavity 06 may overflow, thereby contaminating the active area 04 of the optoelectronic chip 02.

In addition, since the light-transparent cover plate 05 does not contact the active area 04, air will remain between the light-transparent cover plate 05 and the active area 04, and when the package structure is in operation, the problem tends to rise that the air between the light-transparent cover plate 05 and the active area 04 will expand due to heat and cause the light-transparent cover plate 05 to be detached from the molding layer 03.

In order to solve the technical problem, embodiments of the present disclosure provide a package structure comprising a substrate having conductive lines, and along a direction parallel to a surface of the substrate, a part of areas of the substrate are a first substrate, and the remaining areas of the substrate are a second substrate, the base material of the first substrate is a light-transparent material and the first substrate has in it conductive lines, the base material of the second substrate is a non-light-transparent material; and an optoelectronic chip, bonded on the first substrate, the active area of the optoelectronic chip is oriented toward the first substrate, and the active area is arranged staggered with conductive lines in the first substrate, the optoelectronic chip being electrically connected with the conductive lines in the first substrate.

In the package structure provided by the embodiments of the present disclosure, since the base material of the first substrate is a light-transparent material, the active area of the optoelectronic chip is able to receive or emit light through the first substrate to meet the normal work requirements of the optoelectronic chip; moreover, the first substrate is not only capable of realizing electrical connection with the optoelectronic chip, but also capable of realizing sealing protection for the optoelectronic chip, and the use of the first substrate with composite function makes the structure of the package structure simpler and reduces the thickness and volume of the package structure; furthermore, the optoelectronic chip is bonded on the first substrate, and the optoelectronic chip is firmly bonded to the first substrate; in summary, the performance of the package structure may be improved while the space occupied is reduced.

In order to make the above objectives, features, and advantages of the embodiments of the present disclosure more obvious and understandable, the specific embodiments of the present disclosure will be described in detail below in conjunction with the accompanying drawings.

FIG. 2 is a structural schematic diagram of a package structure of the first embodiment of the present disclosure.

In the present embodiment, the package structure includes a first substrate 11, a base material (not labeled) of the first substrate 11 being a light-transparent material, and the first substrate 11 has in it conductive lines 13; an optoelectronic chip 14 bonded on the first substrate 11, an active area 14SR of the optoelectronic chip 14 is oriented toward the first substrate 11, and the active area 14SR is arranged staggered with the conductive lines 13 in the first substrate 11, the optoelectronic chip 14 is electrically connected with the conductive lines 13 in the first substrate 11.

The first substrate 11 is used to support the optoelectronic chip 14, and at the same time, the first substrate 11 has in it conductive lines 13, and the optoelectronic chip 14 is electrically connected with the conductive lines 13 in the first substrate 11, thereby enabling the optoelectronic chip 14 to be electrically connected with external circuits or other electronic elements through the first substrate 11.

The base material of the first substrate 11 is a light-transparent material, and thus, the active area 14SR of the optoelectronic chip 14 is able to receive or emit light through the first substrate 11 to meet the normal work requirements of the optoelectronic chip 14.

The material of the base material of the first substrate 11 includes one or more of glass, silica gel, acrylic, silicon nitride, and silicon oxide. The above materials have better light transmittance and higher process compatibility. In the present embodiment, the material of the base material of the first substrate 11 is glass.

As an example, the base material of the first substrate 11 is a stacked structure, i.e., including multiple layers of stacked base materials, which is easy to meet wiring requirements. It is to be understood that in other embodiments, the base material of the first substrate may also be a single-layer structure, depending on the actual situation.

The conductive lines 13 are wiring structures in the first substrate 11, and the layers of the conductive lines 13 may be multiple layers or a single layer. For example, as shown in FIG. 2, the layers of the conductive lines 13 are multiple layers to meet wiring requirements.

The material of the conductive lines 13 includes a metallic material such as copper or aluminum. In the present embodiment, the material of the conductive lines 13 is copper.

As an example, the conductive lines 13 may comprise a conductive layer 13M as well as a conductive pillar 13V, the conductive layer 13M extends in a transverse direction, and the conductive pillar 13V is electrically connected with the conductive layer 13M in a longitudinal direction. Herein, the transverse direction is parallel to the surface of the first substrate 11, and the longitudinal direction is the direction normal to the surface of the first substrate 11.

In the present embodiment, the first substrate 11 includes a first surface 10A and a second surface 10B arranged facing away from each other, the first surface 10A being used to support the optoelectronic chip 14, and the second surface 10B being used to face away from the optoelectronic chip 14.

The package structure further comprises: a first electrode 13t, located on a first surface 10A of the first substrate 11 and electrically connected with the conductive lines 13; and a second electrode 13b, located on a second surface 10B of the first substrate 11 and electrically connected with the conductive lines 13.

The first electrode 13t serves as an external terminal of the conductive lines 13 at the first surface 10A, and is used to electrically connect electrical properties of the conductive lines 13 to the first surface 10A, and the second electrode 13b serves as an external terminal of the conductive lines 13 on the second surface 10B, and is used to electrically connect the conductive line 13 to the second surface 10B, so that two sides of the first substrate 11 have the function of realizing an electrical connection with the external circuits or electronic elements.

The material of the first electrode 13t includes a metallic material such as copper or aluminum, and the material of the second electrode 13b includes a metallic material such as copper or aluminum. In the present embodiment, the material of the first electrode 13t and the material of the second electrode 13b are both copper.

In the present embodiment, the package structure further comprises a first passivation layer 19t, located on a first surface 10A of the first substrate 11 and exposing a first electrode 13t, and the first passivation layer 19t has in it a third opening 19A passing through the first passivation layer 19t, the third opening 19A being arranged opposite to an active area 14SR of the optoelectronic chip 14; a second passivation layer 19b, located on a second surface 10B and exposing a second electrode 13B, and the second passivation layer 19b has in it a fourth opening 19B passing through the second passivation layer 19b, the fourth opening 19B being arranged opposite to the third opening 19A.

The first passivation layer 19t is used to define the area where the first electrode 13t is exposed, and the second passivation layer 19b is used to define the area where the second electrode 13b is exposed, so as to provide protection to the remaining area and to serve as insulation and prevent oxidation.

In the present embodiment, the first passivation layer 19t and the second passivation layer 19b are also capable of serving as a solder resist layer. Thus, the material of the first passivation layer 19t, and the second passivation layer 19b includes a solder resist ink, such as green oil. In other embodiments, the material of either of the first passivation layer and the second passivation layer may also include polyimide (PI) or a resin.

The first passivation layer 19t has in it a third opening 19A passing through its thickness, the second passivation layer 19b has in it a fourth opening 19B passing through its thickness, and both the third opening 19A and the fourth opening 19B are arranged opposite to the active area 14SR of the optoelectronic chip 14, so that the third opening 19A and the fourth opening 19B provide transmission windows for light.

In the present embodiment, the package structure further comprises a substrate 10 having conductive lines 13, along a direction parallel to the surface of the substrate 10, a part of areas of the substrate 10 have a base material of a light-transparent material and serve as the first substrate 11.

The substrate 10 is a composite substrate, and thus the base material of the substrate 10 in the remaining area may be selected according to actual requirements, for example, for the strength requirements of the substrate 10 in the remaining area, the base material of the substrate 10 in the remaining area may be selected to satisfy the strength requirements of the material, or, for the requirements of small process changes, the base material of the substrate 10 in the remaining area may be selected to be material commonly used in the package process, or, for the functional requirements of the electronic elements provided on the substrate 10 in the remaining area, the base material of the substrate 10 in the remaining area may be selected materials that are adapted to the electronic elements above it.

Correspondingly, the substrate 10 includes a first surface 10A and a second surface 10B arranged facing away from each other, the first surface 10A of the substrate 10 has on it a first electrode 13t electrically connected with the conductive lines 13, and a first passivation layer 19t covering the first surface 10A and exposing the first electrode 13t, and the second surface 10B of the substrate 10 has on it a second electrode 13b electrically connected with the conductive lines 13, and a second passivation layer 19b covering the second surface 10B and exposing the second electrode 13b.

In the present embodiment, the substrate 10 in the remaining area is a second substrate 12, the second substrate 12 also has in it the conductive lines 13, the first surface 10A of the substrate 12 has on it a first electrode 13t electrically connected with the conductive lines 13, and a first passivation layer 19t exposing the first electrode 13t, and the second surface 10B of the substrate 12 has on it a second electrode 13b electrically connected with the conductive lines 13, and a second passivation layer 19b exposing the second electrode 13b.

Specifically, the first passivation layer 19t on the first substrate 11 and the second substrate 12 is a one-piece structure, and the second passivation layer 19b on the first substrate 11 and the second substrate 12 is a one-piece structure.

It can be understood that, according to actual requirements, along a direction parallel to the surface of the substrate 10, the base materials of the second substrate 12 in different areas may all be the same, and the base materials of the second substrate 12 in different areas may be different.

As an example, along the direction parallel to the surface of the substrate, the base material of the substrate 10 in the remaining area is a non-light-transparent material and serves as the second substrate 12. The base material of the second substrate 12 is a non-light-transparent material, which easily meets the strength requirements of the substrate 10 in the remaining area. Moreover, the substrate containing base material of non-light-transparent material is also easy to prepare.

It should be noted that the base material of the second substrate 12 is a non-light-transparent material, so the second substrate 12 can also be used to shield the sidewalls of the first substrate 11 in order to reduce the probability of the first substrate 11 having a problem of side light leakage, and thus to reduce the probability of the performance of the optoelectronic chip 14 being adversely affected.

In the present embodiment, the base material of the second substrate 12 is an epoxy resin. In other embodiments, the base material of the second substrate may also be other opaque insulating materials, such as thermoplastic resins, for example, polycarbonate (PC), polyethylene terephthalate (PET), polyether sulfone, polyphenylene ether, polyamide, polyetherimide, methyl acrylic resin, or cyclic polyolefin-based resins, as well as thermosetting resins, for example, phenolic resin, polyurethane resin, vinyl ester resin, imide-type resins, polyurethane-type resins, urea resin, melamine resin, or organic insulating materials such as polystyrene (PS) and polyacrylonitrile.

In the present embodiment, the first substrate 11 and the second substrate 12 are arranged side-by-side in a direction parallel to the surface of the substrate 10. In other words, the first substrate 11 and the second substrate 12 together provide a first surface 10A of the substrate 10 and together provide a second surface 10B of the substrate 10.

In the present embodiment, the substrate 10 is a one-piece formed substrate, and the sidewalls of the first substrate 11 and the second substrate 12 are in contact with each other. In other words, in the same layer of the base material, a part of area is the base material corresponding to the first substrate 11, and the remaining area is the base material corresponding to the second substrate 12, and thus the first substrate 11 and the second substrate 12 can be obtained at the same time during the preparation process of the substrate 10, thereby making it easy to realize the electrical connection between the conductive lines 13 of the first substrate 11 and the second substrate 12 according to the actual requirements.

In the present embodiment, the base material of the first substrate 11 is a stacked structure, and correspondingly, the base material of the second substrate 12 is also a stacked structure. Specifically, the number of layers of the base material of the first substrate 11 is the same as the number of layers of the base material of the second substrate 12.

In other embodiments, the first substrate and the second substrate are independent of each other, and the first substrate and the second substrate are combined to form a substrate. The first substrate and the second substrate that are independent of each other can be prepared separately, which makes the process of preparing the first substrate and the second substrate simpler and less prone to errors, and which also helps to avoid the impact of the yield problem of one of the first substrate and the second substrate on the other, in addition, it facilitates the timely replacement of the first substrate and the second substrate during the package process when the first substrate and the second substrate are unable to meet the package requirements.

It should be noted that when the first and second substrates are independent of each other, the sidewalls of the first and second substrates may be in contact with each other or spaced apart from each other.

In the present embodiment, the first substrate 11 and the second substrate 12 have conductive lines 13 that are electrically conducting with each other, thereby enabling the electrical connection between the first substrate 11 and the second substrate 12 in the substrate 10, shortening the conductive paths between the two, and thus contributing to the enhancement of the response speed of the package structure. Moreover, if the substrate 10 is bonded onto a PCB (Printed Circuit Board), the electrical connection between the first substrate 11 and the second substrate 12 can be realized without the need to pass through the PCB, thereby reducing the layout requirements for conductive lines on the PCB board.

As an example, the first substrate 11 and the second substrate 12 have connected conductive lines 13 such that the conductive lines 13 of the first substrate 11 and the second substrate 12 achieve conduction within the substrate 10.

Specifically, since the substrate 10 is a one-piece formed substrate, when the conductive lines 13 are formed on the base material corresponding to the first substrate 11 during the preparation of the substrate 10, at least a part of the conductive lines 13 may also be extended to the base material corresponding to the second substrate 12, so that the first substrate 11 and the second substrate 12 have connected conductive lines 13.

It should be noted that in other embodiments, the conductive lines in the first substrate and the conductive lines in the second substrate may also be conducted by means of one or both of the first electrode and the second electrode.

In other embodiments, according to actual requirements, the conductive lines in the first substrate and the conductive lines in the second substrate may also be independent of each other, i.e., the conductive lines in the first substrate and the second substrate do not conduct.

It can be understood that when the first substrate and the second substrate are independent of each other, the first substrate and the second substrate satisfy one or two of the following conditions: the first substrate and the second substrate have connected first electrodes; and the first substrate and the second substrate have connected second electrodes.

Correspondingly, in the case that the first substrate and the second substrate have connected first electrodes, the first passivation layer on the first substrate and the second substrate is a one-piece structure; and in the case that the first substrate and the second substrate have connected second electrodes, the second passivation layer on the first substrate and the second substrate is a one-piece structure.

The optoelectronic chip 14 has a function of realizing the conversion of optical signals and electrical signals, and the optoelectronic chip 14 has an active area 14SR, the active area 14SR is a functional area of the optoelectronic chip 14, and the active area 14SR is used for receiving light or emitting light. Correspondingly, the active area 14SR may be a light-emitting area or a light-sensitive area of the optoelectronic chip 14.

The optoelectronic chip 14 is bonded on the light-transparent first substrate 11 and electrically connected with the conductive lines 13 in the first substrate 11, and the active area 14SR of the optoelectronic chip 14 is oriented toward the first substrate 11, and since the base material of the substrate 11 is a light-transparent material, the active area 14SR of the optoelectronic chip 14 is able to receive or emit light through the first substrate 11 in order to meet the normal working requirements of the optoelectronic chip 14; moreover, the first substrate 11 may not only realize the electrical connection with the optoelectronic chip 14, but also realize the sealing protection of the optoelectronic chip 14, and the use of the composite function of the first substrate 11 makes the structure of the package structure simpler and reduces the thickness and volume of the package structure; in addition, the optoelectronic chip 14 is bonded on the first substrate 11, and the optoelectronic chip 14 and the first substrate 11 are firmly bonded; in summary, the performance of the package structure is improved and the space occupied is reduced.

In the present embodiment, the active area 14SR of the optoelectronic chip 14 is arranged opposite to the third opening 19A and the fourth opening 19B.

In the package structure, the optoelectronic chip 14 may include one or more of a light-sensitive chip and a light-emitting chip. The light-sensitive chip is an optoelectronic chip 14 for receiving light, and the light-emitting chip is an optoelectronic chip 14 for emitting light.

It should be noted that, according to the functional requirements of the package structure, the first substrate 11 may be provided with only a light-sensitive chip, may also be provided with only a light-emitting chip, and may also be provided with a light-sensitive chip and a light-emitting chip.

It can be understood that in the case that a light-sensitive chip and a light-emitting chip are provided on the first substrate 11, according to actual requirements, the light-sensitive chip as well as the light-emitting chip may be provided on the same piece of the first substrate 11, or may be provided on different areas of the first substrate 11 arranged at intervals.

In the present embodiment, the optoelectronic chip 14 is a light-sensitive chip and the active area 14SR is used to receive light. As an example, the optoelectronic chip 14 is an image sensor. In other embodiments, the optoelectronic chip that is the light-sensitive chip may also be a photodiode (PD).

In other embodiments, the optoelectronic chip may also be a light-emitting chip. The active area is used to emit light. For example, the optoelectronic chip may also be a light-emitting diode (LED).

The active area 14SR of the optoelectronic chip 14 faces the first substrate 11, so that the active area 14SR is able to receive or emit light through the first substrate 11 to meet the normal working requirements of the optoelectronic chip 14. Secondly, the active area 14SR is arranged offset from the conductive lines 13 in the first substrate 11 to avoid shielding of the light by the conductive lines 13. Moreover, the optoelectronic chip 14 is electrically connected with the conductive lines 13 so as to realize electrical connection with external circuits or other electronic elements through the conductive lines 13 in the first substrate 11.

In the present embodiment, the optoelectronic chip 14 is flip-flop bonded on the first substrate 11, which is beneficial for reducing the thickness of the package structure. Moreover, the bonding of the optoelectronic chip 14 and the first substrate 11 is realized, while the electrical connection of the optoelectronic chip 14 and the first substrate 11 is realized.

Specifically, the surface of the optoelectronic chip 14 on the side where the active area 14SR is located has connection terminals (not shown in the FIG). The connection terminals are oriented towards the first substrate 11 and thus bonded on the first substrate 11. For example, the connection terminals may be solder pads (pads).

In the present embodiment, taking the optoelectronic chip 14 serving as a first electronic element as an example, the package structure may further comprise a second electronic element 18, located on the substrate 10 (i.e., the second substrate 12) in the remaining area, the functional type of the second electronic element 18 being different from the functional type of the first electronic element.

Since the second electronic element 18 does not need to receive light or emit light, it does not need to be arranged in a light-transparent area.

The functional type of the second electronic element 18 may be selected according to actual requirements, and the second electronic element 18 may include one or two of an active element and a passive element.

For example, the second electronic element 18 may include a peripheral chip. The peripheral chip is an active element with a specific function in the package structure other than the optoelectronic chip 14, and the peripheral chip is used to provide peripheral circuits to the optoelectronic chip 14, such as an analog power supply circuit, a digital power supply circuit, a voltage buffer circuit, a shutter circuit, a shutter drive circuit, and etc. For another example, the second electronic element 18 may also include passive elements such as capacitors, inductors, resistors, etc., so as to play a specific role in the operation of the optoelectronic chip 14.

In the present embodiment, the second electronic element 18 is flip-flop or front-fit bonded on the substrate 10 (i.e., the second substrate 12) in the remaining area.

In the present embodiment, the package structure further comprises a first conductive bump 15A, located between the optoelectronic chip 14 and the first substrate 11 and realizing an electrical connection between the optoelectronic chip 14 and the conductive lines 13 in the first substrate 11.

Specifically, the first conductive bump 15A is located between the optoelectronic chip 14 and the first electrode 13t on the first substrate 11. The first conductive bump 15A not only realizes an electrical connection between the optoelectronic chip 14 and the first substrate 11, but also realizes a bonding between the optoelectronic chip 14 and the first substrate 11 and the bonding strength is relatively high.

Specifically, the surface of the optoelectronic chip 14 has connection terminals (e.g., solder pads), and the first conductive bump 15A connects the connection terminals of the optoelectronic chip 14 with the first electrode 13t on the first substrate 11.

In the present embodiment, the first conductive bump 15A includes a solder ball, a metal pillar, a controllably collapsible chip connection (C4) bump, or a micro-bump, and the first conductive bump 15A may include a conductive material such as solder, copper, aluminum, gold, nickel, silver, palladium, tin, etc. or their combinations.

In the present embodiment, the package structure further comprises a third conductive bump 15C, located between the second electronic element 18 and the substrate 10 in the remaining area (also, i.e., the second substrate 12) and realizing an electrical connection between the second electronic element 18 and the conductive lines 13 in the substrate 10 in the remaining area.

Specifically, the third conductive bump 15C is located between the second electronic element 18 and the first electrode 13t on the substrate 10 in the remaining area. The third conductive bump 15C not only realizes an electrical connection between the second electronic element 18 and the second substrate 12, but also realizes a bonding between the second electronic element 18 and the second substrate 12, and the bonding strength is relatively high.

In the present embodiment, the third conductive bump 15C is a third solder ball, e.g. a C4 type bump.

In the present embodiment, the package structure further comprises: a molding layer 17, located on the first substrate 11 and covering the optoelectronic chip 14, and the molding layer 17 exposing a surface of the first substrate 11 that faces away from the optoelectronic chip 14.

The molding layer 17 is used to protect the optoelectronic chip 14 and mold the optoelectronic chip 14 and the first substrate 11 as a whole to obtain a molding body.

The first substrate 11 is molded together in the package structure by means of the molding layer 17. Thus, the bonding strength of the molding layer 17 with the first substrate 11 is high.

In the present embodiment, the molding layer 17 also covers the second electronic element 18.

In the present embodiment, the material of the molding layer 17 is a molding material, for example, epoxy resin. The epoxy resin has the advantages of low shrinkage, good adhesion, good corrosion resistance, excellent electrical properties, and low cost. In other embodiments, other suitable package materials may be selected for the molding layer.

In the present embodiment, the molding layer 17 exposes the surface of the first substrate 11 facing away from the optoelectronic chip 14, enabling the active area 14SR of the optoelectronic chip 14 to receive or emit light through the first substrate 11, and also facilitates the subsequent realization of the electrical connection between the first substrate 11 and the external circuitry.

In the present embodiment, the package structure further comprises a first filler layer 19A, located between the optoelectronic chip 14 and the first substrate 11 and covering the first conductive bump 15A, the first filler layer 19A being a light-transparent material.

The first filler layer 19A fills the space between the optoelectronic chip 14 and the first substrate 11, reducing the probability that the molding layer 17 fills into the space between the optoelectronic chip 14 and the first substrate 11, thereby reducing the probability that the molding layer 17 shields the active area 14SR. Moreover, the first filler layer 19A is a light-transparent material, thereby enabling the active area 14SR to receive or emit light through the first filler layer 19A.

In the present embodiment, the material of the first filler layer 19A comprises a light-transparent resin. In other embodiments, other underfill materials that are light-transparent may also be selected as the first filler layer.

In the present embodiment, the package structure further comprises a second conductive bump 15B, located on the second surface 10B of the first substrate 11 and the second substrate 12, the second conductive bump 15B being electrically connected with the conductive lines 13.

The second conductive bump 15B is used to realize the electrical connection of the first substrate 11 with the external circuits.

Specifically, the second conductive bump 15B is located on the second electrode 13b and electrically connected with the second electrode 13b, and thus is electrically connected with the conductive lines 13 via the second electrode 13b.

As an example, the second conductive bump 15B is a second solder ball, for example, a tin ball.

In other embodiments, the second conductive bump may also include a metal pillar and a metal cap covering a top surface of the metal pillar. For example, the metal pillar may be a copper pillar, and the material of the metal cap may include tin or a tin alloy.

FIG. 3 is a structural schematic diagram of a package structure of the second embodiment of the present disclosure.

The similarities between the present embodiment and the aforementioned embodiments are not repeated herein. The difference between the present embodiment and the aforementioned embodiments lies in that the molding layer 27 also covers the sidewalls of the first substrate 21.

Since the base material of the first substrate 21 is a light-transparent material, the molding layer 27 is thus used to shield the sidewalls of the first substrate 21 to reduce the probability of the first substrate 21 having a problem of side light leakage, and thus reduce the probability of the performance of the optoelectronic chip being adversely affected.

For example, when the first substrate 21 is located at an edge position of the substrate (not labeled), a part of the sidewalls of the first substrate 21 is exposed, and the sidewalls of the first substrate 21 that are not in contact with the second substrate may be covered by the molding layer 27.

Specifically, the molding layer 27 has a lower light transmittance, and thus is able to better serve as a light shield. Moreover, making the molding layer 27 to cover the sidewalls of the first substrate 21 also enables the molding layer 27 to be used to play a protective role for the sidewalls of the first substrate 21, and reduce the probability of rupture of the first substrate 21.

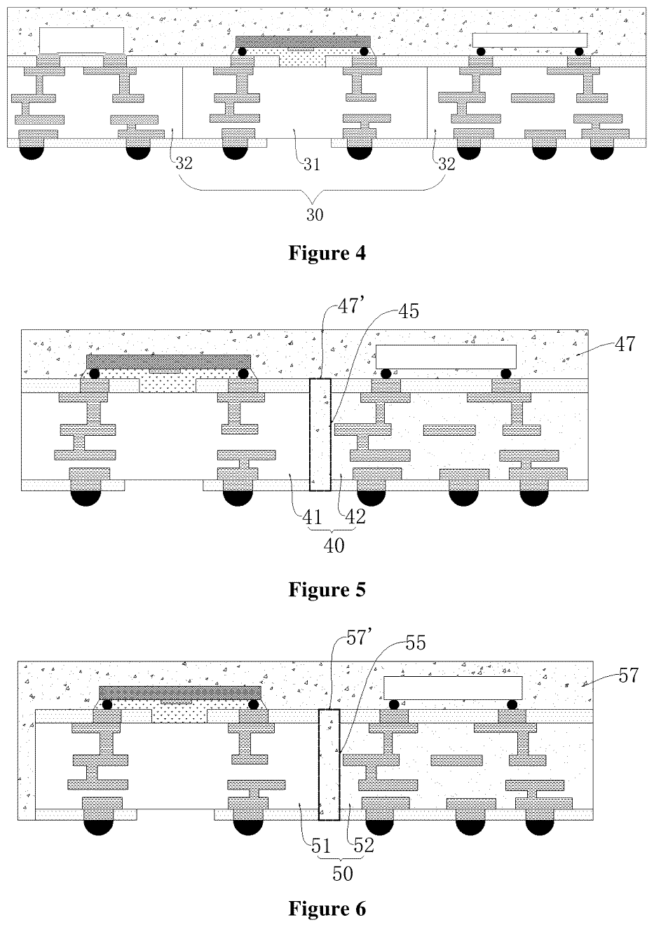

FIG. 4 is a structural schematic diagram of a package structure of the third embodiment of the present disclosure.

The similarities between the present embodiment and the aforementioned embodiments are not repeated herein. The difference between the present embodiment and the aforementioned embodiments lies in that the substrate 30 in the remaining area is a second substrate 32, and the second substrate 32 surrounds a sidewall of the first substrate 31.

The second substrate 32 surrounds the sidewall of the first substrate 31, and thus the second substrate 32 can be used to shield the sidewall of the first substrate 31 in order to reduce the probability of the first substrate 31 having a problem of side light leakage.

Specifically, various sidewalls of the first substrate 31 are in contact with the second substrate 32.

FIG. 5 is a structural schematic diagram of the package structure of the fourth embodiment of the present disclosure.

The similarities between the present embodiment and the aforementioned embodiments will not be repeated herein. The difference between the present embodiment and the aforementioned embodiments lies in that the substrate 40 comprises a first substrate 41 and a second substrate 42 that are independent of each other and spaced apart from each other, and the sidewalls of the first substrate 41 and the second substrate 42 enclose a groove

The sidewalls of the first substrate 41 and the second substrate 42 are spaced apart from each other so that the stress due to the difference in the coefficients of thermal expansion of the two is dispersed, thereby reducing the probability of warping of the first substrate 41 and the second substrate 42.

Correspondingly, in the present embodiment, the package structure may further comprise a second filler layer 47′ of a non-light-transparent material, filled in the groove 45.

The second filler layer 47′ is filled in the grooves 45 to fill the space between the first substrate 41 and the second substrate 42 in order to mold the first substrate 41 and the second substrate 42 into the same package structure.

A second filler layer 67′ of a non-light-transparent material is used to reduce the probability of the first substrate 41 having a problem of side light leakage.

In the present embodiment, the molding package layer 47 is also filled in the groove 45, and the molding package layer 47 in the groove 45 serves as a second filler layer 47′. On the one hand, this simplifies the process steps for preparing the package structure, and on the other hand, the package structure does not introduce another material layer, thereby further improving the warping problem.

In other embodiments, according to actual requirements, the second filler layer of the non-light-transparent material may also be made of other suitable materials, for example, the material of the second filler layer may include a resin or a bonding adhesive, so as to realize the bonding between the first substrate and the second substrate. For example, the material of the second filler layer may include: phenolic resin, epoxy resin, bismaleimide triazine resin, epoxy acrylate, poly propylene glycol (PPG), ABF, etc.

In other embodiments, when a combination of a first substrate and a second substrate independent of each other is used to form a substrate, the package structure may also comprise a pre-molding layer, filled in the groove, with the pre-molding layer in the groove serving as a second filler layer.

In this case, the first substrate and the second substrate may also satisfy one or two of the following conditions: the first substrate and the second substrate have connected first electrodes; the first substrate and the second substrate have connected second electrodes.

The substrate may be a pre-molding substrate, and thus a first electrode may be uniformly prepared on a first surface of the substrate after obtaining the pre-molding substrate, and the first substrate and the second substrate may have connected first electrodes, or a second electrode may be uniformly prepared on a second surface of the substrate after obtaining the pre-molding substrate, and the first substrate and the second substrate may have connected second electrodes, thereby realizing an electrical connection between the first substrate and the second substrate.

FIG. 6 is a structural schematic diagram of a package structure of the fifth embodiment of the present disclosure.

The similarities between the present embodiment and the fourth embodiment are not repeated herein. The difference between the present embodiment and the fourth embodiment lies in that the molding layer 57 also covers a sidewall of the first substrate 51.

The substrate 50 includes a first substrate 51 and a second substrate 52 that are independent of each other and spaced apart from each other, and the sidewalls of the first substrate 51 and the second substrate 52 enclose a groove 55, and the molding layer 57 is also filled in the groove 55 to serve as a second filler layer 57′, so as to cover the respective sidewalls of the first substrate 51 by the molding layer 57 to reduce the probability of side light leakage on the first substrate 51.

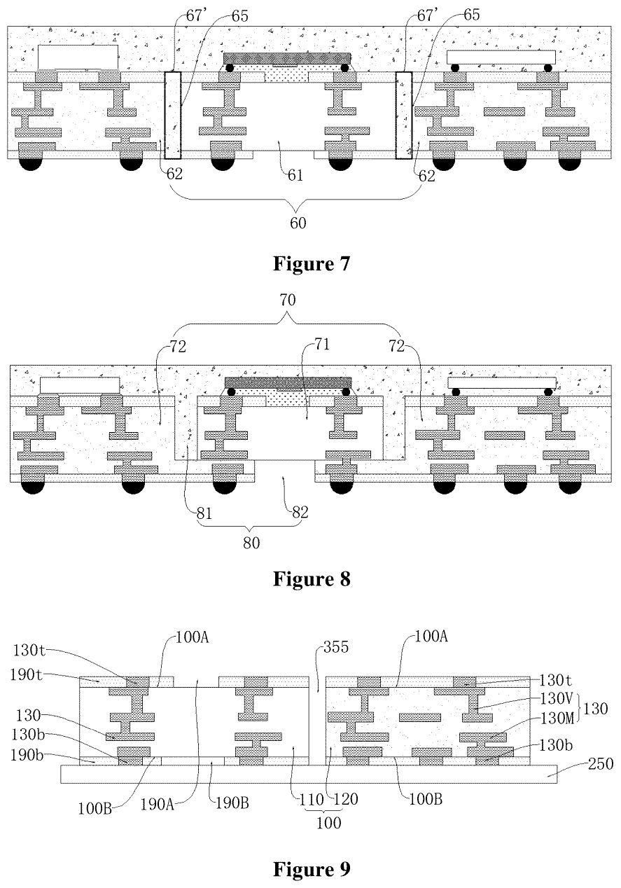

FIG. 7 is a structural schematic diagram of a package structure of the sixth embodiment of the present disclosure.

The similarities between the present embodiment and the third embodiment will not be repeated herein. The difference between the present embodiment and the third embodiment lies in that: the substrate 60 includes a first substrate 61 and a second substrate 62 that are independent of each other and spaced apart from each other, and the sidewalls of the first substrate 61 and the second substrate 62 enclose a groove 65.

Correspondingly, the package structure may further comprise a second filler layer 67′ of a non-light-transparent material, filled in the groove 65 to reduce the probability of the first substrate 61 having a problem of side light leakage. As an example, the molding layer 67 is also filled in the groove 65, and the molding layer 67 in the groove 65 serves as the second filler layer 67′.

FIG. 8 is a structural schematic diagram of a package structure of the seventh embodiment of the present disclosure.

The similarities between the present embodiment and the aforementioned embodiments will not be repeated herein. The difference between the present embodiment and the aforementioned embodiments lies in that the second substrate 72 has in it an opening 80 passing through the second substrate 72, and the opening 80 includes a first opening 81 and a second opening 82 that are connected through each other, and the opening dimension (not labeled) of the first opening 81 is larger than the opening dimension (not labeled) of the second opening 82; the first substrate 71 is located in the first opening 81; and an active area of the optoelectronic chip (not labeled) is arranged opposite to the second opening 82.

The first substrate 71 is located in the first opening 81, and thus is combined with the second substrate 72 to form the substrate 70.

Moreover, the opening dimension of the first opening 81 is larger than the opening dimension of the second opening 82, such that the opening 80 has a step so that the first substrate 71 can be provided on the step and the second substrate 72 can support the first substrate 71, which improves the stability of the bonding of the two, and also facilitates the simplification of the process steps for preparing the substrate 70 (e.g., without the need to use an additional carrier substrate).

In the present embodiment, at least a part of the conductive lines (not labeled) in the first substrate 71 are electrically connected with the conductive lines exposed at the first opening 81 in the second substrate 72, thereby realizing the electrical connection between the first substrate 71 and the second substrate 72 while using the independent first substrate 71 and the second substrate 72 to form the substrate 70, and it is also able to increase the bonding strength between the first substrate 71 and the second substrate 72 through the connection of the conductive lines.

Specifically, at least a part of the conductive lines in the first substrate 71 are electrically connected with the conductive lines in the second substrate 72 that are exposed at the bottom of the first opening 81, which not only reduces the complexity of realizing the electrical connection between the first substrate 71 and the second substrate 72, but also improves the reliability of the connection between the conductive lines of the first substrate 71 and the conductive lines of the second substrate 72.

It should be noted that in other embodiments, at least a part of the conductive lines in the first substrate are electrically connected with the conductive lines in the second substrate that are exposed at the sidewall of the first opening.

In the present embodiment, the first substrate 71 and the sidewall of the first opening 81 are spaced apart from each other, thereby reducing the difficulty in placing the first substrate 71 in the first opening 81, and allowing the stress due to the difference in the coefficients of thermal expansion of the first substrate 71 and the second substrate 72 to be dispersed.

The first substrate 71 and the sidewall of the first opening 81 enclose a groove (not labeled). Correspondingly, the package structure may further comprise a second filler layer (not labeled) of a non-light-transparent material filled in the groove. As an example, the molding layer (not labeled) is also filled in the groove, and the molding layer in the groove serves as the second filler layer.

FIGS. 9 to 13 are schematic diagrams corresponding to the steps in the first embodiment of the package method of the present disclosure.

Referring to FIG. 9, a first substrate 110 is provided. The base material of the first substrate 110 is a light-transparent material, and the first substrate 110 has in it conductive lines 130.

The first substrate 110 is used to support the optoelectronic chip, and at the same time, the first substrate 110 has in it conductive lines 130, and the conductive lines 130 in the first substrate 110 are used to electrically connect with the optoelectronic chip, so as to enable the optoelectronic chip to be electrically connected with external circuits or other electronic elements through the first substrate 110.

The base material of the first substrate 110 is a light-transparent material, enabling the active area of the optoelectronic chip to receive or emit light through the first substrate 110.

The material of the base material of the first substrate 110 includes one or more of glass, silica gel, silicon nitride, and silicon oxide. In the present embodiment, the material of the base material of the first substrate 110 is glass.

As an example, the base material of the first substrate 110 is a stacked structure. In other embodiments, the base material of the first substrate may also be a single layer structure according to actual requirements.

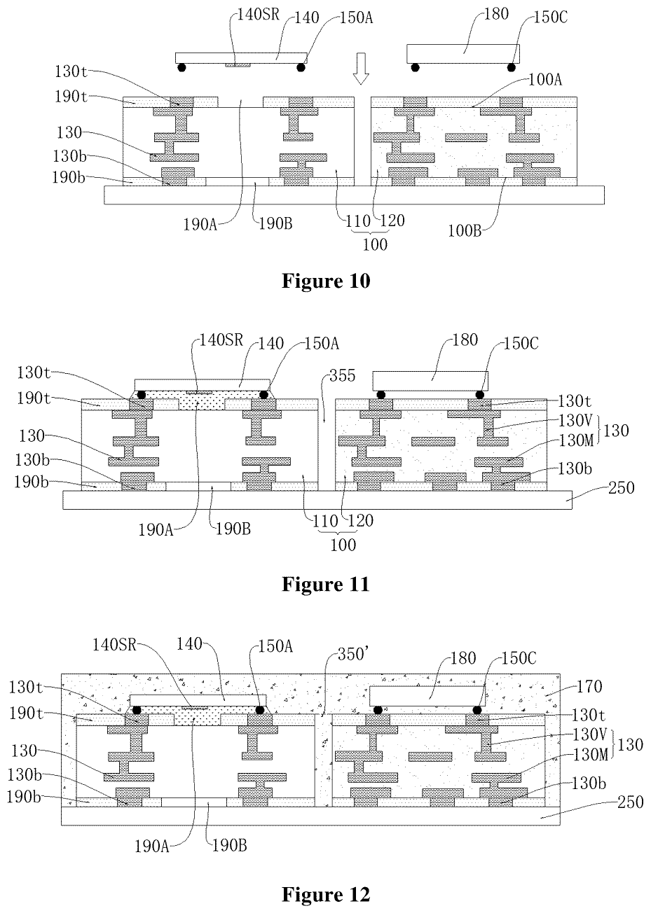

The conductive lines 130 are wiring structures in the first substrate 110, and the number of layers of the conductive lines 130 may be multiple layers or a single layer. For example, as shown in FIG. 10, the number of layers of the conductive lines 130 is multiple layers.

In the present embodiment, the first substrate 110 includes a first surface 100A and a second surface 100B arranged facing away from each other, the first surface 100A being used to support the optoelectronic chip, and the second surface 100B being used to face away from the optoelectronic chip.

A first electrode 130t electrically connected with the conductive lines 130, and a first passivation layer 190t covering the first surface 100A and exposing the first electrode 130t is formed on the first surface 100A of the first substrate 110, the first passivation layer 190t has in it a third opening 190A passing through the first passivation layer 190t, a second electrode 130b electrically connected with the conductive lines 130, and a second passivation layer 190b covering the second surface 100B and exposing the second electrode 130b are formed on the second surface 100B of the first substrate 110, the second passivation layer 190b has in it a fourth opening 190B passing through the second passivation layer 190b, the fourth opening 190B being arranged opposite to the third opening 190A.

The third opening 190A and the fourth opening 190B are both used to provide a transmission window for light when the optoelectronic chip is operating.

In the present embodiment, the step of providing the first substrate 110 includes providing the substrate 100 having the conductive lines 130, along a direction parallel to the surface of the substrate 100, the base material of a part of area of the substrate 100 is a light-transparent material, and serves as the first substrate 110.

The substrate 100 is a composite substrate, and thus the base material of the substrate 100 in the remaining area can be selected according to the actual requirements.

In the present embodiment, the substrate 100 in the remaining area is the second substrate 120. It is to be understood that, according to actual requirements, along the direction parallel to the surface of the substrate 100, the base materials of the second substrate 120 in different areas may all be the same, and the base materials of the second substrate 120 in different areas may be different.

The second substrate 120 also has in it the conductive lines 130, a first electrode 130t electrically connected with the conductive lines 130, and a first passivation layer 190t exposing the first electrode 130t are on the first surface 100A of the second substrate 120, and a second electrode 130b electrically connected with the conductive lines 130, and a second passivation layer 190b exposing the second electrode 130b are on the second surface 100B of the second substrate 120.

In the present embodiment, the first substrate 110 and the second substrate 120 are arranged side-by-side in a direction parallel to the surface of the substrate 100.

As an example, in the step of providing the substrate 100 having the conductive lines 130, the base material of the substrate 100 in the remaining area is a non-light-transparent material and serves as the second substrate 120.

The base material of the second substrate 120 is a non-light-transparent material, and thus it is easy to meet the strength requirements for the substrate 100 in the remaining area. Moreover, the substrate 100 comprising the base material of the non-light-transparent material is easy to prepare. It is also easy to use the second substrate 120 to shield the sidewalls of the first substrate 110 to reduce the probability of the first substrate 110 having a problem of side light leakage, and thus reduce the probability of the performance of the optoelectronic chip being adversely affected.

In the present embodiment, the base material of the second substrate 120 is an epoxy resin. In other embodiments, the base material of the second substrate may also be other opaque insulating materials.

Specifically, the step of providing the substrate 100 having the conductive lines 130 includes providing a carrier substrate 250; arranging a first substrate 110 and a second substrate 120 on the carrier substrate 250, respectively, so that the first substrate 110 and the second substrate 120 form the substrate 100.

The first substrate 110 and the second substrate 120 are independent of each other, and the carrier substrate 250 is used to realize the temporary bonding, and thus the carrier substrate 250 is used to provide an operating platform for the subsequent package steps.

The first substrate 110 and the second substrate 120 are independent of each other, and thus the first substrate 110 and the second substrate 120 can be prepared separately, which makes the process of preparing the first substrate 110 and the second substrate 120 simpler and less prone to error, and also helps to avoid the impact of the yield problem of one of the first substrate 110 and the second substrate 120 on the other, in addition, in the process of package, it is convenient to timely replace the first substrate 110 and the second substrate 120 when either of the first substrate 110 and the second substrate 120 cannot meet the package requirements.

It should be noted that in the step of providing the first substrate 110 and the second substrate 120 on the carrier substrate 250, respectively, the sidewalls of the first substrate 110 and the second substrate 120 may be in contact with each other or may be spaced apart from each other.

As shown in FIG. 9, in the present embodiment, the first substrate 110 and the second substrate 120 are independent of each other and spaced apart from each other, and the sidewalls of the first substrate 110 and the second substrate 120 enclose a groove 355. The sidewalls of the first substrate 110 and the second substrate 120 are spaced apart from each other, which allows the stresses generated by the difference in the coefficients of thermal expansion of the two to be dispersed, thereby reducing the probability of the first substrate 110 and the second substrate 120 having a warping.

In conjunction with reference to FIGS. 10 and 11, the optoelectronic chip 140 is bonded on the first substrate 110, the active area 140SR of the optoelectronic chip 140 is oriented toward the first substrate 110, and the active area 140SR is provided in a staggered manner with the conductive lines 130 in the first substrate 110, and the optoelectronic chip 140 is electrically connected with the conductive lines 130 in the first substrate 110.

The optoelectronic chip 140 has a function of realizing the conversion of light signals and electrical signals, and the optoelectronic chip 140 has an active area 140SR, and the active area 140SR is used to receive light or emit light. Correspondingly, the active area 140SR may be a light-emitting area or a light-sensitive area of the optoelectronic chip 140.

In the present embodiment, in the step of bonding the optoelectronic chip 140 on the first substrate 110, the active area 140SR of the optoelectronic chip 140 is arranged opposite to the third opening 190A and the fourth opening 190B.

The optoelectronic chip 140 may include one or more of a light-sensitive chip and a light-emitting chip. It should be noted that, according to the functional requirements of the package structure, the light-sensitive chip may be arranged only on the first substrate 110, or the light-emitting chip may be arranged only on the first substrate 110, or the light-sensitive chip and the light-emitting chip may be arranged on the first substrate 110.

It is to be understood that in the case that a light-sensitive chip and a light-emitting chip are provided on the first substrate 110, according to actual requirements, the light-sensitive chip as well as the light-emitting chip may be provided on the same piece of the first substrate 110, or may be provided on different areas of the first substrate 110 provided at intervals.

The active area 140SR of the optoelectronic chip 140 faces toward the first substrate 110, so that the active area 140SR is able to receive or emit light through the first substrate 110 to meet the normal working requirements of the optoelectronic chip 140. Secondly, the active area 140SR is arranged staggered with the conductive lines 130 in the first substrate 110 to avoid shielding of the light by the conductive lines 130. Moreover, the optoelectronic chip 140 is electrically connected with the conductive lines 130 in the first substrate 110, so as to realize electrical connection with external circuits or other electronic elements through the conductive lines 130 in the first substrate 110.

In the present embodiment, the optoelectronic chip 140 is flip-flop bonded on the first substrate 110, which is conducive to reducing the thickness of the package structure. By means of flip-flop bonding, not only the electrical connection between the optoelectronic chip 140 and the first substrate 110 is realized, but also the bonding of the optoelectronic chip 140 to the first substrate 110 is realized with a high bonding strength.

Specifically, the surface of the optoelectronic chip 140 on the side where the active area 140SR is located has connection terminals (not shown in the figures). The connection terminals are oriented toward the first substrate 110 and thus bonded on the first substrate 110. For example, the connection terminals may be solder pads (pads).

Specifically, the step of bonding the optoelectronic chip 140 on the first substrate 110 includes bonding the optoelectronic chip 140 on the first substrate 110 using the first conductive bump 150A to realize an electrical connection between the optoelectronic chip 140 and the conductive lines 130 in the first substrate 110.

The first conductive bump 150A not only realizes the electrical connection between the optoelectronic chip 140 and the first substrate 110, but also realizes the bonding of the optoelectronic chip 140 with the first substrate 110 with a high bonding strength.

Specifically, the first conductive bump 150A is located between the optoelectronic chip 140 and the first electrode 130t on the first substrate 110.

In the present embodiment, the optoelectronic chip 140 is used as the first electronic element, and the package method may further include arranging a second electronic element 180 on the substrate 100 (also i.e., the second substrate 120) in the remaining area, the second electronic element 180 is electrically connected with the conductive lines 130 in the substrate 100 in the remaining area, and the functional type of the second electronic element 180 is different from the functional type of the first electronic element.

Since the second electronic element 180 does not need to receive light or emit light, it does not need to be provided in a light-transparent area. The functional type of the second electronic element 180 may be selected according to actual requirements.

Specifically, the step of providing the second electronic element 180 on the substrate 100 (also, i.e., the second substrate 120) in the remaining area includes: bonding the second electronic element 180 to the second substrate 120 using a third conductive bump 150C to realize an electrical connection between the second electronic element 180 and the conductive lines 130 in the second substrate 120.

Specifically, the third conductive bump 150C is located between the second electronic element 180 and the first electrode 130t on the second substrate 120.

It should be noted that, according to the actual requirements, after the first substrate 110 and the second substrate 120 are made to form the substrate 100, the optoelectronic chip 140 is bonded on the first substrate 110; or, after bonding the optoelectronic chip 140 on the first substrate 110, the first substrate 110 and the second substrate 120 are made to form the substrate 100.

Similarly, according to the actual requirements, the second electronic element 180 is arranged on the second substrate 120 after the first substrate 110 and the second substrate 120 are made to form the substrate 100; or, the first substrate 110 and the second substrate 120 are made to form the substrate 100 after the second electronic element 180 is arranged on the second substrate 120.

As can be seen, the flexibility of the package process is improved by using the first substrate 110 and the second substrate 120, which are independent of each other.

As an example, a first substrate 110 and a second substrate 120 are respectively arranged on the carrier substrate 250, after the first substrate 110 and the second substrate 120 are made to form the substrate 100, an optoelectronic chip 140 is bonded on the first substrate 110, and a second electronic element 180 is arranged on the second substrate 120.

Referring to FIG. 11, after bonding the optoelectronic chip 140 on the first substrate 110 and before forming a molding layer covering the optoelectronic chip 140, the package method further includes forming a first filler layer 190A between the optoelectronic chip 140 and the first substrate 110, the first filler layer 190A covering the first conductive bumps 150A, and the first filler layer 190A being a light-transparent material.

The first filler layer 190A fills the space between the optoelectronic chip 140 and the first substrate 110, reducing the probability of the molding layer filling into the space between the optoelectronic chip 140 and the first substrate 110, thereby reducing the probability of the molding layer shielding the active area 140SR. Moreover, the first filler layer 190A is a light-transparent material, thereby enabling the active area 140SR to receive or emit light through the first filler layer 190A.

In the present embodiment, the material of the first filler layer 190A includes a light-transparent resin. In other embodiments, the first filler layer may also be made of other bottom filler materials that are light-transparent.

Referring to FIG. 12, a molding layer 170 covering the optoelectronic chip 140 is formed on the first substrate 110, the molding layer 170 exposing a surface of the first substrate 110 facing away from the optoelectronic chip 140.

The molding layer 170 is used to protect the optoelectronic chip 140 and to mold the optoelectronic chip 140 with the first substrate 110 together as a whole to obtain a molding body.

It should be noted that the first substrate 110 is molded together in the package structure by the molding layer 170, and thus the bonding strength between the molding layer 170 and the first substrate 110 is high, which is conducive to enhancing the performance of the package structure.

It should be noted that since the active area 140SR of the optoelectronic chip 140 is oriented toward the first substrate 110, and since the first filler layer 190A is filled between the first substrate 110 and the active area 140SR, the optoelectronic chip 140 is able to be completely packaged in the molding layer 170, and thus the probability of dust or particles having an effect on the transmission of light can be reduced, thus improving the performance stability of the optoelectronic chip 140.

In the present embodiment, the molding layer 170 also covers the second electronic element 180.

In the present embodiment, the material of the molding layer 170 is a molding material, e.g., an epoxy resin.

In the present embodiment, the molding layer 170 exposes the surface of the first substrate 110 facing away from the optoelectronic chip 140, such that the active area 140SR of the optoelectronic chip 140 may receive or emit light through the first substrate 110. Moreover, it facilitates the subsequent realization of the electrical connection of the first substrate 110 with the external circuitry.

It should be noted that the molding layer 170 may expose the sidewalls of the first substrate 110, and the molding layer 170 may also cover the sidewalls of the first substrate 110. Since the base material of the first substrate 110 is a light-transparent material, the molding layer 170 is thus used to cover the sidewalls of the first substrate 110 in order to reduce the probability of the first substrate 110 having a problem of side light leakage, and thus reduce the probability of the performance of the optoelectronic chip being adversely affected. For example, when the first substrate 110 is located at an edge position of the substrate 100, a part of the sidewalls of the first substrate 110 is exposed, and the sidewalls of the first substrate 110 that are not in contact with the second substrate 120 may be covered by the molding layer 170.

Specifically, the molding layer 170 has a low light transmittance, and thus can better play a role of light shielding. Moreover, making the molding layer 170 to cover the sidewalls of the first substrate 110 also enables the molding layer 170 to be used to play a protective role for the sidewalls of the first substrate 110, and reduce the probability of rupture of the first substrate 110.

It is also noted that since the sidewalls of the first substrate 110 and the second substrate 120 enclose a groove 355 (as shown in FIG. 11), the package method may also include filling the groove 355 with a second filler layer 350′ of a non-light-transparent material.

A second filler layer 350′ is filled in the groove 355 to fill the space between the first substrate 110 and the second substrate 120, so as to mold the first substrate 110 and the second substrate 120 into the same package structure.

A second filler layer 350′ of a non-light-transparent material is used to reduce the probability of the first substrate 110 having problems with side light leakage.

In the present embodiment, the molding layer 170 is also filled in the groove 355, and the molding layer 170 in the groove 355 serves as a second filler layer 350′. On the one hand, this simplifies the process steps for preparing the package structure, and on the other hand, the package structure does not introduce another material layer, thus further improving the warping problem.

In other embodiments, the second filler layer of the non-light-transparent material may also be selected from other suitable materials and formed separately according to actual requirements, e.g., the material of the second filler layer may include a resin or a bonding adhesive so as to realize the bonding between the first substrate and the second substrate.

In other embodiments, it is also possible to form a pre-molding layer filled in the groove by means of pre-molding before bonding the optoelectronic chip on the first substrate, the pre-molding layer serving as a second filler layer.

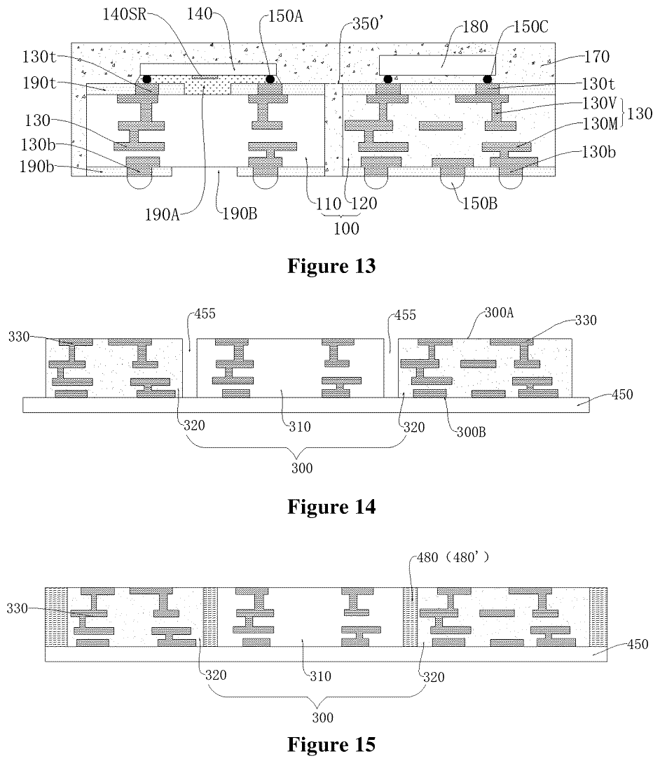

Referring to FIG. 13, in the present embodiment, after forming the molding layer 170, the package method further includes removing the carrier substrate 250 to expose a surface of the first substrate 110 facing away from the optoelectronic chip 140.

Continuing with reference to FIG. 13, the package method further includes forming, on a second surface 100B of the first substrate 110, a second conductive bump 150B electrically connected with the conductive lines 130.

The second conductive bump 150B is used to realize the electrical connection of the first substrate 110 with the external circuitry.

Specifically, the second conductive bump 150B is located on the second electrode 130b and electrically connected with the second electrode 130b, and thus is electrically connected with the conductive lines 130 through the second electrode 130b.

As an example, the second conductive bump 150B is a second solder ball, e.g., a tin ball.

In other embodiments, the second conductive bump may also include a metal pillar and a metal cap covering a top surface of the metal pillar. For example, the metal pillar may be a copper pillar, and the material of the metal cap may include tin or a tin alloy.

It should be understood that during the packaging process, a plurality of products are usually molded together. In other words, after being molded by the molding layer 170 to obtain a molding body, the molding body includes a plurality of products, each of which includes an optoelectronic chip 140, and thus the package method further includes: cutting the molding body into individual products.

As an example, it is possible to cut the molding body into individual products after forming the second conductive bump 150B. In other embodiments, it is also possible to cut the molding body into individual products before forming the second conductive bump.

FIGS. 14 to 17 are schematic diagrams corresponding to the steps in the second embodiment of the package method of the present disclosure.

The similarities between the present embodiment and the first embodiment are not repeated herein. The difference between the present embodiment and the first embodiment lies in that the conductive lines 330 of the first substrate 310 and the second substrate 320 are electrically connected.

In the present embodiment, the first substrate 310 and the second substrate 320 are independent of each other, and the first substrate 310 and the second substrate 320 form into the substrate 300.

Referring to FIG. 14, a carrier substrate 450 is provided, and a first substrate 310 and a second substrate 320 are provided on the carrier substrate 450, respectively, such that the first substrate 310 and the second substrate 320 form the substrate 300.

In the present embodiment, the second substrate 320 surrounds a sidewall of the first substrate 310.

The second substrate 320 surrounds the sidewall of the first substrate 310, thus the second substrate 320 can provide a certain shielding effect on the sidewall of the first substrate 31 to reduce the probability of the first substrate 310 having a problem of side light leakage.

In other embodiments, the second substrate may also not surround the sidewall of the first substrate. For example, the first substrate and the second substrate are arranged side-by-side in a direction parallel to the surface of the substrate, with the first substrate being located on one side of the second substrate.

In the present embodiment, the first substrate 310 and the second substrate 320 are independent of each other and spaced apart from each other, and the sidewalls of the first substrate 310 and the second substrate 320 enclose a groove 455. In other embodiments, in the case that the second substrate surrounds the sidewall of the first substrate, the sidewalls of the first substrate and the second substrate may also be in contact.

In the present embodiment, in the step of providing the first substrate 310 and the second substrate 320 on the carrier substrate 450, respectively, the conductive lines 330 are exposed on both the first surface 300A and the second surface 300B of the substrate 300. In other words, the first electrode and the second electrode are not formed on either of the first substrate 310 and the second substrate 320.

In other embodiments, a first electrode is formed on a first surface of the first substrate and the second substrate. In other embodiments, a second electrode is formed on a second surface of the first substrate and the second substrate.

As an example, the first electrode is subsequently formed first on the first surface 300A, and thus the second surface 300B is oriented toward the carrier substrate 450. In other embodiments, the second electrode is subsequently formed first on the second surface, and thus the first surface is oriented toward the carrier substrate.

Referring to FIG. 15, the groove 455 is filled with a second filler layer 480 of a non-light-transparent material.

Specifically, the step of filling the groove 455 with the second filler layer 480 of a non-light-transparent material includes pre-molding the first substrate 310 and the second substrate 320 to form a pre-molding layer 480′ filled in the groove 455, the pre-molding layer 480′ serving as the second filler layer 480.

The first substrate 310 and the second substrate 320 are first pre-molded, which is conducive to improving the flexibility of the packaging process and facilitating the realization of the electrical connection of the first substrate 310 and the second substrate 320.

In the present embodiment, the material of the pre-molding layer 480′ is a molding material, e.g., an epoxy resin.

In the present embodiment, the pre-molding layer 480′ may also cover a sidewall of the second substrate 320.

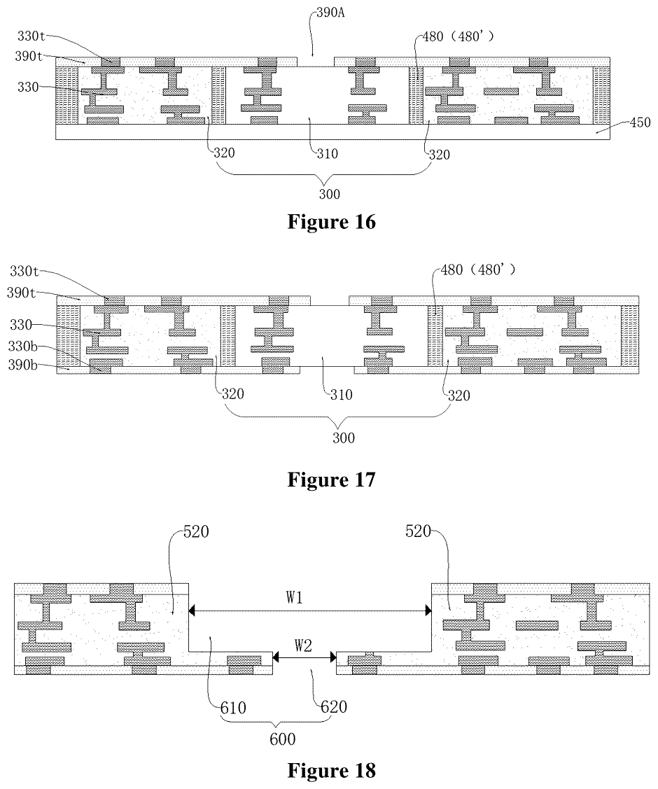

Referring to FIGS. 16 and 17, after pre-molding the first substrate 310 and the second substrate 320, one or both of the first electrode 330t and the second electrode 330b are formed on the substrate 300.

It should be noted that the conductive lines 330 in the first substrate 310 and the conductive lines 330 in the second substrate 320 may be electrically connected by means of one or both of the first electrode 330t and the second electrode 330b.

In the case that the first electrode 330t is formed after the first substrate 310 and the second substrate 320 are made to form the substrate 300, the first electrode 330t is located on a first surface 300A (as shown in FIG. 14) of the substrate 300, the first substrate 310 and the second substrate 320 have connected first electrodes 330t, and the first electrodes 330t are electrically connected with the conductive lines 330; and in the case that the second electrode 330b is formed after the first substrate 310 and the second substrate 320 are made to the substrate 300, the second electrode 330b is located on the second surface 300B (as shown in FIG. 14) of the substrate 300, the first substrate 310 and the second substrate 320 have connected second electrodes 330b, and the second electrodes 330b are electrically connected with the conductive lines 330.

It should be noted that the formation of the first electrode 330t or the second electrode 330b is facilitated by pre-molding the first substrate 310 and the second substrate 320, which in turn facilitates the electrical connection of the conductive lines 330 in the first substrate 310 and the second substrate 320 by means of one or both of the first electrode 330t and the second electrode 330b.

The conductive lines 330 in the first substrate 310 and the second substrate 320 are electrically connected, which is conducive to shortening the conductive paths of the two, so that it in turn is conducive to improving the response speed of the package structure. Moreover, if the substrate is subsequently bonded onto a PCB board, there is no need to achieve an electrical connection between the first substrate and the second substrate through the PCB board, which in turn can reduce the layout requirements for the conductive lines on the PCB board.

Referring to FIG. 16, a first electrode 330t is formed on a first surface 300A (shown in FIG. 14) of the substrate 300, and the first electrode 330t is electrically connected with the conductive line 330.

Specifically, the first substrate 310 and the second substrate 320 have connected first electrodes 330t.

Continuing with reference to FIG. 16, after forming the first electrode 330t on the first surface 300A of the substrate 300 (as shown in FIG. 14), a first passivation layer 390t exposing the first electrode 330t is formed on the first surface 300A of the substrate 300, the first passivation layer 390t has in it a third opening 390A passing through the first passivation layer 390t.

After forming the first passivation layer 390t, it further comprises removing the carrier substrate 450.

Referring to FIG. 17, after removing the carrier substrate 450, a second electrode 330b is formed on the second surface 300B (shown in FIG. 14) of the substrate 300, and the second electrode 330b is electrically connected with the conductive line 330.

Specifically, the first substrate 310 and the second substrate 320 have connected second electrodes 330b.

Continuing with reference to FIG. 17, after forming the second electrode 330b on the second surface 300B of the substrate 300 (as shown in FIG. 14), a second passivation layer 390b exposing the second electrode 330b is formed on the second surface 300B of the substrate 300, the second passivation layer 390b has in it a fourth opening (not labeled) passing through the second passivation layer 390b, the fourth opening being arranged opposite to the third opening 390A.

In the present embodiment, the first passivation layer 390t on the first substrate 310 and the second substrate 320 is a one-piece structure, and the second passivation layer 390b on the first substrate 310 and the second substrate 320 is a one-piece structure.

It should be noted that the subsequent steps are the same as the first embodiment, and therefore are not repeated.

FIGS. 18 to 20 are schematic diagrams corresponding to each step in the third embodiment of the package method of the present disclosure.

The similarities between the present embodiment and the aforementioned embodiments are not repeated herein. The difference between the present embodiment and the aforementioned embodiments lies in that the first substrate 510 is assembled in the second substrate 520.

Referring to FIG. 18, a second substrate 520 is provided. The second substrate 520 has in it an opening 600 passing through the second substrate 520, and the opening 600 includes a first opening 610 and a second opening 620 that are connected through each other, the opening dimension WI of the first opening 610 is larger than the opening dimension W2 of the second opening 620.

The opening dimension W1 of the first opening 610 is larger than the opening dimension W2 of the second opening 620, such that the opening 600 has a step so that the first substrate can be arranged on the step and the second substrate 520 can support the first substrate, which improves the combining stability of the two and also facilitates the simplification of the process steps for preparing the substrate (e.g., without the need to use an additional carrier substrate).

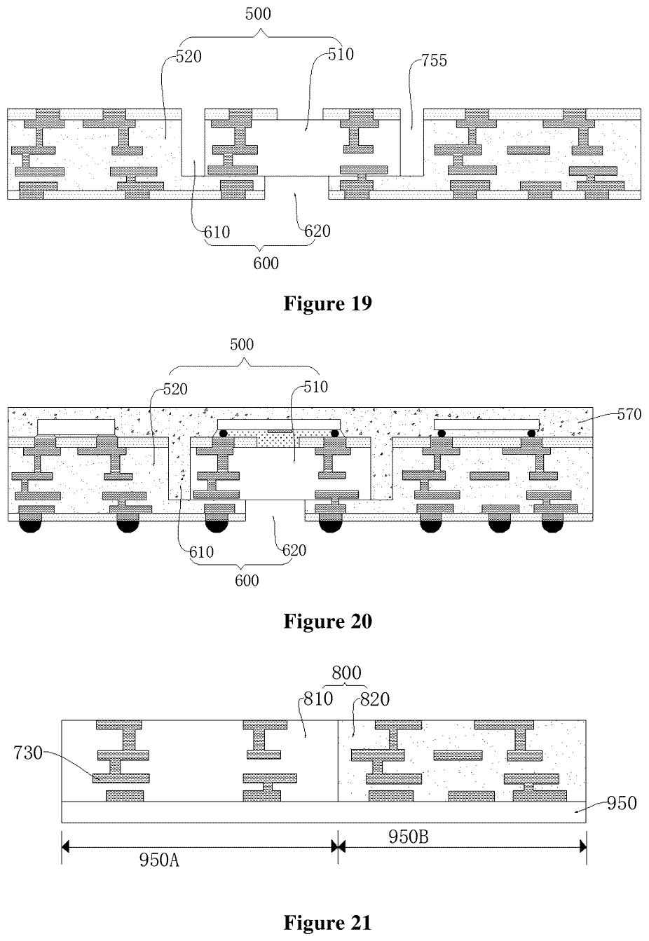

Referring to FIG. 19, a first substrate 510 is arranged in the first opening 610 such that the first substrate 510 and the second substrate 520 form the substrate 500.

In the present embodiment, at least a part of the conductive lines (not labeled) in the first substrate 510 are electrically connected with the conductive lines in the second substrate 520 that are exposed at the first opening 610, so as to realize the electrical connection between the first substrate 510 and the second substrate 520 while adopting the combination of the independent first substrate 510 and the second substrate 520 to form the substrate 500, moreover, the bonding strength between the first substrate 510 and the second substrate 520 can be improved through the connection of the conductive lines.

Specifically, at least a part of the conductive lines in the first substrate 510 are electrically connected with the conductive lines in the second substrate 520 that are exposed at the bottom of the first opening 610, which not only reduces the difficulty of realizing the electrical connection between the first substrate 510 and the second substrate 520, but also improves the reliability of the connection between the conductive lines of the first substrate 510 and the conductive lines of the second substrate 520.

Specifically, the first substrate 510 is bonded at the bottom of the first opening 610, and the exposed conductive lines of the first substrate 510 are bonded with the conductive lines exposed at the bottom of the first opening 610, and the metal-to-metal bonding improves the bonding strength between the first substrate 510 and the second substrate 520. In other embodiments, it is also possible to fix the first substrate 510 at the bottom of the first opening 610 by means of a conductive adhesive or solder, and meanwhile realize an electrical connection between the conductive lines of the first substrate 510 and the conductive lines of the second substrate 520.

It should be noted that in other embodiments, at least a part of the conductive lines in the first substrate are electrically connected with the conductive lines in the second substrate exposed at the sidewall of the first opening.

In the present embodiment, the first substrate 510 is spaced apart from the sidewall of the first opening 610, thereby reducing the difficulty of placing the first substrate 510 in the first opening 610, and allowing stresses due to differences in the coefficients of thermal expansion of the first substrate 510 and the second substrate 520 to be dispersed. Correspondingly, the first substrate 510 and the sidewall of the first opening 610 enclose a groove 755.

Referring to FIG. 20, an optoelectronic chip (not labeled) is bonded on the first substrate 510, and a second electronic element (not labeled) is provided on the second substrate 520.

In the present embodiment, in the step of bonding the optoelectronic chip on the first substrate 510, an active area (not labeled) of the optoelectronic chip is arranged opposite to the second opening 620.

Continuing with reference to FIG. 20, a molding layer 570 covering the optoelectronic chip is formed on the first substrate 510. Specifically, the molding layer 570 is formed on the substrate 500.

In the present embodiment, the package method further comprises forming, in the groove 755, a second filler layer (not labeled) of a non-light-transparent material. As an example, in the step of forming the molding layer 570, the molding layer 570 is also filled in the groove 755, and the molding layer 570 in the groove 755 serves as the second filler layer.

It should be noted that the steps after the first substrate 510 and the second substrate 520 form the substrate 500 are the same as in the aforementioned embodiments and thus will not be repeated.

It should be noted that in the first embodiment to the third embodiment, it is illustrated by taking usage of independent first substrate and second substrate to form a substrate as an example. In other embodiments, a one-piece formed substrate may also be used.

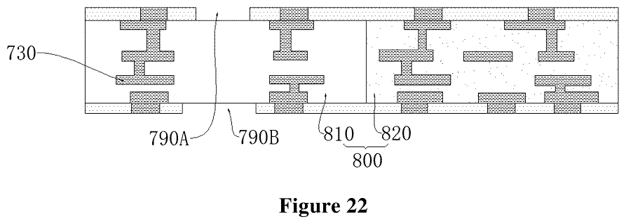

FIGS. 21 to 22 are schematic diagrams corresponding to the steps in the fourth embodiment of the package method of the present disclosure.

The similarities between the present embodiment and the aforementioned embodiments are not repeated herein. The difference between the present embodiment and the aforementioned embodiments lies in that the step of providing the substrate 800 having the conductive lines 730 includes providing a one-piece formed substrate 800, along a direction parallel to the surface of the substrate 800, the base material of a part of area of the substrate 800 is a light-transparent material and serving as a first substrate 810, and the remaining area of the substrate 800 being a second substrate 820, and the sidewalls of the first substrate 810 and the second substrate 820 are in contact.

The substrate 800 is a one-piece formed substrate 800, that is to say, in the same layer of base material, a part of the area is the base material corresponding to the first substrate 810, and the remaining area is the base material corresponding to the second substrate 820, and thus in the process of the preparation of the substrate 800, it is possible to obtain the first substrate 810 and the second substrate 820 at the same time, and thus it is easy to realize the electrical connection between the conductive lines 730 of the first substrate 810 and the second substrate 820 according to the actual requirements.

It should be noted that the first substrate 810 and the second substrate 820 have connected conductive lines 730, thereby enabling an electrical connection between the first substrate 810 and the second substrate 820 in the substrate.

As an example, in the one-piece formed substrate 800, the base material of the first substrate 810 is a stacked structure. Correspondingly, the base material of the second substrate 820 is also a stacked structure. Specifically, the number of layers of the base material of the first substrate 810 is the same as the number of layers of the base material of the second substrate 820.

Referring to FIG. 21, the step of providing a one-piece formed substrate 800 includes: providing a carrier substrate 950 including adjacent first area 950A and second area 950B; performing one or more wiring treatments on the carrier substrate 950 to form a first substrate 810 located in the first area 950A and a second substrate 820 located in the second area 950B, and obtaining a one-piece formed substrate 800; the step of wiring treatment includes: forming a base material (not labeled) on the carrier substrate 950, including a first base material (not labeled) formed in the first area 950A and a second base material (not labeled) formed in the second area 950B, the first base material being a light-transparent material and the second base material being a non-light-transparent material; in the first area 950A and the second area 950B, conductive lines are formed on the surface of the base material or in the interior of the base material.

The first base material is used to prepare the first substrate 810, and the second base material is used to prepare the second substrate 820. In the case that the number of wiring treatments is a plurality of times, the first base material formed by the plurality of wiring treatments constitutes a stacked structure, and the second base material formed by the plurality of wiring treatments constitutes a stacked structure.

It should be noted that in each wiring treatment process, a first base material will be formed in the first area 950A, and a second base material will be formed in the second area 950B. Therefore, in any step of wiring treatment, when forming conductive lines 730 on the first base material and the second base material, at least a part of the conductive lines 730 on the first base material and the second base material can be brought into connect.

It is also should be noted that in the present embodiment, the first substrate 810 and the second substrate 820 are arranged side-by-side in a direction parallel to the surface of the substrate 800, with the first substrate 810 being located on one side of the second substrate 820. In other embodiments, the second substrate may also surround the sidewalls of the first substrate, and the respective sidewalls of the first substrate are in contact with the second substrate, so as to use the second substrate to shield the sidewalls of the first substrate, to reduce the probability of the first substrate having a problem of side light leakage.

Referring to FIG. 22, after obtaining the one-piece formed substrate 800, the package method further includes forming, on a first surface (not shown) of the first substrate 810, a first electrode (not shown) electrically connected with the conductive lines 730, and a first passivation layer covering the first surface and exposing the first electrode, the first passivation layer has in it a third opening 790A passing through the first passivation layer; forming, on a second surface (not shown) of the first substrate 810, a second electrode (not shown) electrically connected with the conductive lines, and a second passivation layer covering the second surface and exposing the second electrode, the second passivation layer has in it a fourth opening 790B passing through the second passivation layer, and the fourth opening 790B is arranged opposite to the third opening 790A.

In the present embodiment, the first electrode and the first passivation layer are further formed on a first surface of the second substrate 820, and the second electrode and the second passivation layer are further formed on a second surface of the second substrate 820. Specifically, the first passivation layer on the first substrate and the second substrate are one-piece structure, and the second passivation layer on the first substrate and the second substrate are one-piece structure.

It should be noted that prior to forming the first electrode or the second electrode on the surface of the substrate 800 oriented toward the carrier substrate 950, the package method further includes removing the carrier substrate 950.

It is also noted that the subsequent steps are the same as in the aforementioned embodiments and therefore will not be repeated.

It should be noted that the package structure of the aforementioned embodiment may be obtained by using the package method of the aforementioned embodiment, or may be obtained by using other package methods, and for the specific description of the package method of the aforementioned embodiment, reference may be made to the relevant description of the package structure.

Although the present disclosure is disclosed as above, the present disclosure is not limited thereto. Any person skilled in the art may make various changes and modifications without departing from the spirit and scope of the present disclosure, and therefore the scope of protection of the present disclosure shall be defined by the scope limited by the claims.

What is claimed is:

1. A package structure, comprising:
a substrate having conductive lines along a direction parallel to a surface of the substrate, wherein a part of areas of the substrate is a first substrate, remaining areas of the substrate are a second substrate, a base material of the first substrate is a light-transparent material, the first substrate has the conductive lines, and a base material of the second substrate is a non-light-transparent material; and
an optoelectronic chip bonded on the first substrate, wherein an active area of the optoelectronic chip is oriented toward the first substrate, the active area is arranged staggered with the conductive lines in the first substrate, and the optoelectronic chip is electrically connected with the conductive lines in the first substrate.

2. The package structure according to claim 1, further comprising:
a first conductive bump located between the optoelectronic chip and the first substrate and realizing an electrical connection between the optoelectronic chip and the conductive lines in the first substrate.

3. The package structure according to claim 2, further comprising:
a molding layer located on the first substrate and covering the optoelectronic chip, the molding layer exposing a surface of the first substrate facing away from the optoelectronic chip; and
a first filler layer located between the optoelectronic chip and the first substrate and covering the first conductive bump, the first filler layer being a light-transparent material.

4. The package structure according to claim 3, wherein a material of the first filler layer comprises a light-transparent resin.

5. The package structure according to claim 1, wherein
the optoelectronic chip serves as a first electronic element;
the package structure further comprises a second electronic element located on the substrate in a remaining area and electrically connected with conductive lines in the substrate in the remaining area; and
a functional type of the second electronic element is different from that of the first electronic element.

6. The package structure according to claim 1, wherein
the first substrate and the second substrate are arranged side-by-side in a direction parallel to the surface of the substrate; or
the second substrate has in it an opening passing through the second substrate, and the opening comprises a first opening and a second opening that are connected through each other, an opening dimension of the first opening being larger than an opening dimension of the second opening;
the first substrate is located in the first opening;
the active area of the optoelectronic chip is arranged opposite the second opening.

7. The package structure according to claim 6, wherein in a case that the second substrate has an opening passing through the second substrate, at least a part of the conductive lines in the first substrate are electrically connected with the conductive lines in the second substrate exposed at the first opening.

8. The package structure according to claim 7, wherein at least a part of the conductive lines in the first substrate are electrically connected with conductive lines in the second substrate exposed at a bottom of the first opening.

9. The package structure according to claim 1, wherein
the substrate is a one-piece formed substrate, and sidewalls of the first substrate and the second substrate are in contact; or
the first substrate and the second substrate are independent of each other.

10. The package structure according to claim 9, wherein
the first substrate and second substrate are independent of each other and spaced apart from each other, and the sidewalls of the first substrate and second substrate enclose a groove; and
the package structure further comprises a second filler layer of non-light-transparent material filled in the grooves.

11. The package structure according to claim 10, wherein a material of the second filler layer comprises a resin or bonding adhesive.

12. The package structure according to claim 10, further comprising:
a molding layer located on the first substrate and covering the optoelectronic chip, the molding layer exposing a surface of the first substrate facing away from the optoelectronic chip, the molding layer being filled in the groove, the molding layer in the groove serving as a second filler layer; or
a pre-molding layer filled in the groove, the pre-molding layer in the groove serving as a second filler layer.

13. The package structure according to claim 5, wherein the second substrate surrounds a sidewall of the first substrate.

14. The package structure according to claim 5, wherein the first substrate and the second substrate have conductive lines that are conducting with each other.

15. The package structure according to claim 9, wherein
the first and second substrates are independent of each other;
the package structure comprises:
a first electrode located on a first surface of the substrate and electrically connected with the conductive lines, the first surface is configured to support the optoelectronic chip; and
a second electrode located on a second surface of the substrate and electrically connected with the conductive lines, the second surface is configured to surface away from the optoelectronic chip; and
the first substrate and the second substrate satisfy at least one of the following conditions: the first substrate and the second substrate have connected first electrodes; and the first substrate and the second substrate have connected second electrodes.

16. The package structure according to claim 1, further comprising:
a first electrode located on a first surface of the first substrate and electrically connected with the conductive lines, the first surface is configured to support an optoelectronic chip;
a second electrode located on a second surface of the first substrate and electrically connected with the conductive lines, the second surface is configured to surface away from the optoelectronic chip;
a first passivation layer located on the first surface of the first substrate and exposing the first electrode, the first passivation layer having a third opening passing through the first passivation layer, the third opening being arranged opposite the active area of the optoelectronic chip; and
a second passivation layer located on the second surface of the first substrate and exposing the second electrode, the second passivation layer having a fourth opening passing through the second passivation layer, the fourth opening being arranged opposite to the third opening,
wherein the active area of the optoelectronic chip is arranged opposite the third opening and the fourth opening.

17. The package structure according to claim 1, wherein a material of the base material of the first substrate comprises at least one of glass, silica gel, acrylic, silicon nitride, or silicon oxide.

18. The package structure according to claim 1, further comprising:
a molding layer located on the first substrate and covering the optoelectronic chip, the molding layer exposing a surface of the first substrate facing away from the optoelectronic chip, and the molding layer further covering a sidewall of the first substrate.

19. The package structure according to claim 1, further comprising:
a second conductive bump located on a second surface of the first substrate, the second conductive bump being electrically connected with the conductive lines, the second surface being facing away from the optoelectronic chip.

20. The package structure according to claim 1, wherein the optoelectronic chip comprises one or more of a light-sensitive chip and a light-emitting chip.
